(19) United States
(12) Patent Application Publication
(10) Pub. No.: US 2012/0217969 A1
(43) Pub. Date: Aug. 30, 2012

(54) LED PROBE

(75) Inventors: XIANG CAO, Shenzhen City (CN); HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/118,443

(22) Filed: May 29, 2011

(30) Foreign Application Priority Data
Feb. 24, 2011 (CN) 201110044480.8

(51) Int. Cl. G01R 31/00

(52) U.S. Cl. 324/414

(57) ABSTRACT

A probe includes a main body and a sensor circuit board. The main body includes a through hole capable of accommodating an LED under test and an accommodation space capable of accommodating the sensor circuit board. The main body is made of opaque material. The sensor circuit board includes a light sensor, a body and a connector. The light sensor is opposite to the through hole. The probe separates the light sensor and the LED under test from ambient light, thereby enhancing the precision of test results.

### BACKGROUND

1. Technical Field

The present disclosure relates to a light-emitting diode (LED) probe.

2. Description of Related Art

An in-circuit tester (ICT) is generally for testing the components of a circuit board. In addition, some ICTs in the market are capable of testing the characteristics of a light emitting diode (LED) such as the brightness by aiming an LED sensor of a probe of the ICT at the LED under test. However, since the probe of the ICT and the LED under test are generally exposed during testing, ambient light may adversely affect the test results. Thus, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is an exploded view of a light emitting diode probe of one embodiment of the present disclosure.

FIG. 2 is an assembled view of the LED probe of FIG. 1.

FIG. 3 is a schematic diagram of a combination of three of the LED probe of FIG. 1.

### DETAILED DESCRFIPTION

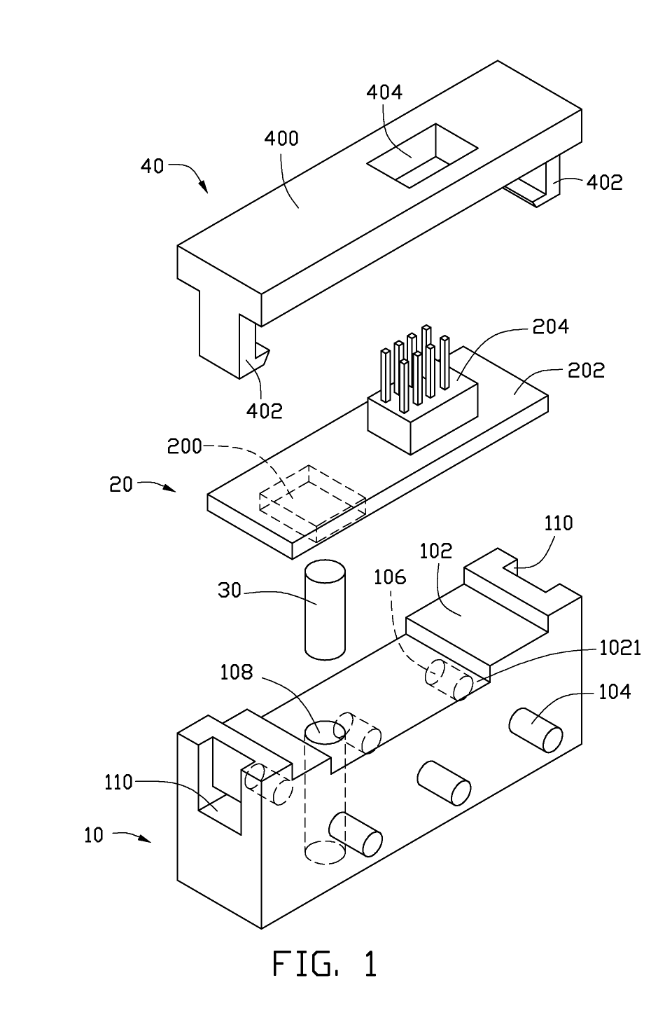

As shown in FIG. 1, a light emitting diode (LED) probe includes a main body 10, a sensor circuit board 20, a light pipe 30, and a fixing unit 40. The board 20 includes a light sensor 200, a body 202, and a connector 204. The light sensor 200 and the connector 204 are disposed on a bottom surface and a top surface of the body 202, respectively, and are electrically connected to each other. The connector 204 transmits light signals detected by the light sensor 200, to an external test device (not shown).

The main body 10 having an approximately rectangular cuboid shape is made of opaque material such as black-colored plastic. A top surface of the main body 10 has an accommodation space 102 defined therein in a shape capable of accommodating the board 20. In this embodiment, the top surface of the main body 10 has a recess 1021 defined adjacent to the accommodation space 102 which is capable of accommodating the light sensor 200 and a bottom portion of the connector 204. In other embodiments, the top surface of the main body 10 can have a recess defined adjacent to the accommodation space 102 which is capable of enclosing the light sensor 200 between the main body 10 and the board 20. The main body 10 has a through hole 108 corresponding to the light sensor 200, which is defined through the top surface and a bottom surface of the main body 10. One sidewall of the main body 10 has three holes 106 defined therein, while an opposite sidewall of the main body 10 has three protrusions 104 extending therefrom and corresponding to the three holes 106. Each of surfaces of two opposite ends of the body 10 has a groove 110 defined therein.

The light pipe 30 is a cylinder which has a diameter corresponding to the through hole 108 and is shorter than the through hole 108, so that the light pipe 30 can be inserted into the through hole 108.

The fixing unit 40 having a shape approximate to ‘II’ includes a body 400 and two hooks 402. The body 400 has a rectangular hole 404 corresponding to the connector 204. The shanks of the two hooks 402 perpendicularly extend from two opposite edges of a surface of the body 40, respectively, while each of the hooking portion of the two hooks 402 perpendicularly extends from the shanks and pointing toward each other.

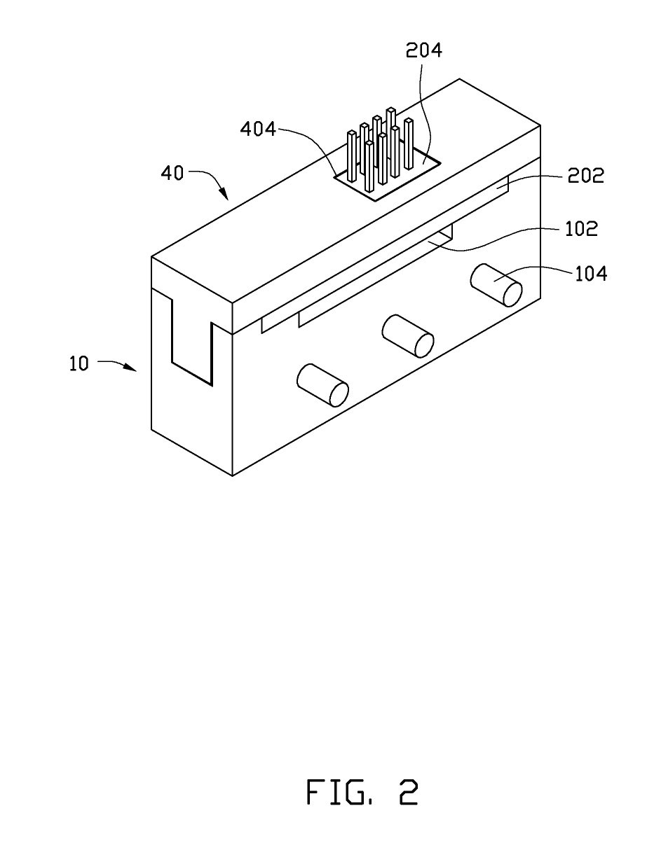

As shown in FIG. 2, after assembling the LED probe of FIG. 1, the body 202 is accommodated in the accommodation space 102, and the fixing unit 40 is fastened to the body 10. Correspondingly, the two hooks 402 are wedged into the two recesses 110 of the body 10, respectively, the connecter 204 extends through the rectangular hole 404, and the through hole 108 is opposite to the light sensor 200. Consequently, the board 20 is fixed in the accommodation space 102. In this embodiment, a gap is kept between the light sensor 200 and the through hole 108. However, in other embodiments, the light sensor 200 can touch edges or be inserted into the through hole 108.

When using the LED probe, the light pipe 30 is inserted into the through hole 108 from the bottom surface of the main body 10, to test the LED without interference from ambient light. The light pipe 30 transmits light from the LED under test to the light sensor 200. The connector 204 transmits the light signals detected by the light sensor 200 to an external test device (not shown), thereby the light can be analyzed and a determination of whether the LED is qualified can be made.

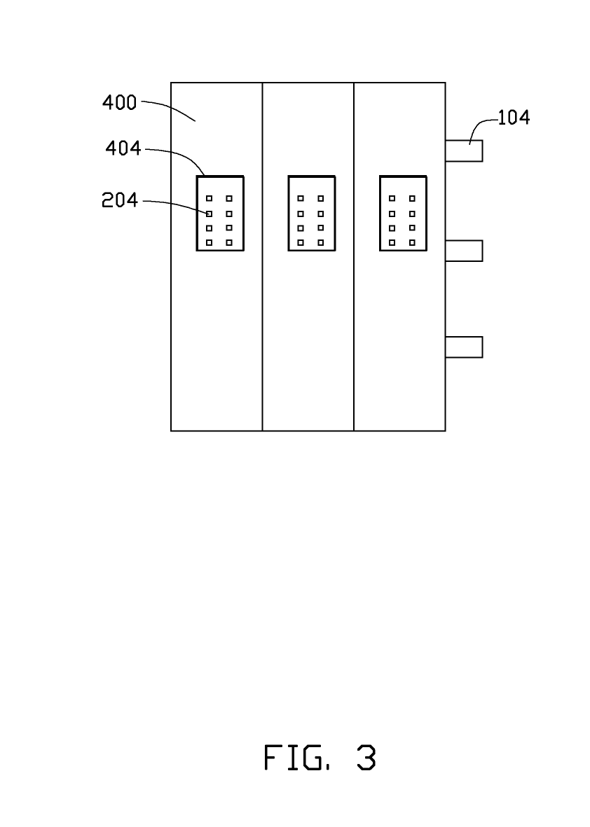

As shown in FIG. 3, when there are multiple LEDs to be tested, multiple LED probes can be combined by, for instance, inserting three protrusions 104 of a main body 10 of a LED probe into three holes 106 of a main body 10 of another LED probe, respectively.

However, in other embodiments, the board 20 can be a circuit board of an ICT. Consequently, tests can be performed by fixing the main body 10 on the circuit board of the ICT. In addition, the light pipe 30 can be omitted, the light of the LED under test directly measured. Furthermore, other types of light guide units such as an optical fiber can be used to substitute for the light pipe 30, thereby transmitting the light of the LED to the light sensor 200.

The LED probe separates the light sensor and the LED under test from ambient light, thereby enhancing the precision of test results

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A light-emitting diode (LED) probe, comprising:
a main body including a through hole capable of accommodating an LED under test and an accommodation space, wherein the main body is made of opaque material; and
a sensor circuit board including a light sensor, a body and a connector, wherein the light sensor is opposite to the through hole of the main body and the sensor circuit board is accommodated in the accommodating space.

2. The LED probe of claim 1, wherein the main body further includes a light guide unit disposed in the through hole.

3. The LED probe of claim 1, wherein the light guide unit is a light pipe.

4. The LED probe of claim 1, wherein the light guide unit is an optical fiber.

5. The LED probe of claim 1, wherein the main body has a recess defined adjacent to the accommodation space for accommodating at least one of the light sensor and the connector of the sensor circuit board.

6. The LED probe of claim 1, wherein the main body has a recess defined adjacent to the accommodation space for enclosing the light sensor of the sensor circuit board between the main body and the sensor circuit board.

7. The LED probe of claim 1, wherein further comprises a fixing unit including a body and two hooks, a recess is defined on a surface of two opposite ends of the body, the shanks of the two hooks perpendicularly extend from two opposite edges of a surface of the body, respectively, while each of the hooking portion of the two hooks perpendicularly extends from the shanks and pointing toward each other, the two hooks are wedged into the recesses to fasten the fixing unit with the body.

8. The LED probe of claim 1, wherein the light sensor and the connector are disposed on two opposite surfaces of the sensor circuit board.

9. The LED probe of claim 8, wherein further comprises a fixing unit including a body and two hooks, the body has a rectangular hole corresponding to the connector, a recess is defined on a surface of two opposite ends of the body, the two hooks perpendicularly protrude from two opposite edges of a surface of the body, each of the two hooks perpendicularly protrudes from one of the two opposite edges and extends toward the other of the two opposite edges, the two hooks are wedged into the recesses to fasten the fixing unit with the body.

10. The LED probe of claim 1, wherein two opposite sides of the body respectively includes at least a hole and at least a protrusion opposite to each other.

11. The LED probe of claim 1, wherein the opaque material is black-colored plastic.
